(19) United States
(12) Patent Application Publication
(10) Pub. No.: US 2026/0068553 A1
(43) Pub. Date: Mar. 5, 2026

(54) Ion Beam-Induced Epitaxial Crystallization on an Integrated Processing Architecture

(71) Applicant: Applied Materials, Inc., Santa Clara, CA (US)

(72) Inventors: Michael Noel Kennedy, Boston, MA (US); Christopher R. Hatem, Seabrook, NH (US); Joseph C. Olson, Beverly, MA (US); Arianna Donatella Rivera, Gainesville, FL (US)

(73) Assignee: Applied Materials, Inc., Santa Clara, CA (US)

(21) Appl. No.: 18/824,260

(22) Filed: Sep. 4, 2024

(51) Int. Cl. H01L 21/02; C23C 16/02; C23C 16/48; C23C 16/50; C30B 1/00; C30B 31/22; H01J 37/32; H01L 21/67

(52) U.S. Cl. CPC H01L 21/02667; C23C 16/0227; C23C 16/486; C23C 16/50; C30B 1/00; C30B 31/22; H01J 37/32899; H01J 2237/332; H01J 2237/335

(57) ABSTRACT

Disclosed herein are methods and systems for epitaxial crystallization on an integrated processing architecture. In some embodiments, a method may include performing a first plasma treatment on a semiconductor substrate to remove a native oxide layer along an upper surface of the semiconductor substrate, and forming a film layer over the upper surface by performing a second plasma treatment on the semiconductor substrate. The method may further include performing an ion implantation process to crystallize the film layer, wherein the implant process comprises delivering an ion species to the film layer while the semiconductor substrate is at a temperature greater than 100° C.

### FIELD OF THE DISCLOSURE

The present embodiments relate to approaches for epitaxial crystallization and, more particularly, to a method and apparatus for ion beam-induced epitaxial crystallization on an integrated beamline architecture.

### BACKGROUND OF THE DISCLOSURE

Single-crystal, poly-crystalline, and amorphous semiconducting materials have different electronic properties, and it is often desirable when producing semiconductor devices to be working with single-crystalline materials. Some integration schemes for producing semiconductor devices require the deposition and patterning of amorphous or polycrystalline films on top of single-crystalline wafers that are used as substrates. Fabrication flows also frequently involve the implantation of dopant atoms into device layers at energies which damage the crystal lattice, and ion implantation is even purposefully used to amorphize films in so-called “pre-amorphization implant” (PAI) in advance of additional ion implantation and device processing. Amorphous or polycrystalline films are frequently transformed into the desired single crystals at later points in fabrication flows via annealing to facilitate epitaxial growth from an underlying single-crystalline interface, which acts as a “seed” for the formation of the crystal lattice above it. However, the high temperatures required for this annealing can create problems in complex integration schemes for advanced node device fabrication, and limit potential fabrication flows.

Film transformation can also be achieved via ion beam-induced epitaxial crystallization or recrystallization. Films that were once crystalline before experiencing PAI or implant damage are recrystallized, while those films which were deposited as amorphous or polycrystalline films are crystallized for the first time. Epitaxial crystallization is most successful at forming the desired single-crystal material without inclusions or crystal lattice defects when there is a clean interface with no defects between the crystalline seed material and the material being crystallized. However, silicon grows a native oxide layer extremely rapidly with any exposure to oxygen, which functions as a defect layer for the purposes of epitaxial crystallization.

Accordingly, improved approaches for ion beam induced epitaxial crystallization treatment of semiconductor device films are needed.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include performing a first plasma treatment on a semiconductor substrate to remove a native oxide layer along an upper surface of the semiconductor substrate, and subsequently depositing a film layer over the upper surface by performing a second plasma treatment on the semiconductor substrate. The method may further include performing an implant process to crystallize the film layer, wherein the implant process comprises delivering an ion species to the film layer while the semiconductor substrate is at a temperature greater than 100° C.

In another aspect, a method of processing a film layer formed over a semiconductor substrate may include performing a first plasma treatment on a semiconductor substrate to remove a native oxide layer along an upper surface of the semiconductor substrate, and subsequently depositing a film layer over the upper surface by performing a second plasma treatment on the semiconductor substrate following removal of the native oxide layer. The method may further include performing an implant process to crystallize the film layer, wherein the implant process comprises delivering an ion species to the film layer while the semiconductor substrate is at a temperature between 100° C. and 500° C., wherein the first plasma treatment is performed by a first processing tool in a first chamber, wherein the second plasma treatment is performed by a second processing tool in a second chamber connected to the first chamber via a load-lock system, and wherein the implant process is performed by a third processing tool in a third chamber connected to the first and second chambers via the load-lock system. The semiconductor substrate is maintained under vacuum during the first plasma treatment, the second plasma treatment, and the implant process, and during transfer between the first chamber, the second chamber, and the third chamber.

In yet another aspect, a semiconductor cluster tool may include a first processing tool in a first chamber, wherein the first processing tool is operable to perform a first plasma treatment on a semiconductor substrate to remove a residue along an upper surface of the semiconductor substrate. The semiconductor cluster tool may further include a second processing tool in a second chamber, wherein the second chamber is connected to the first chamber by a load-lock system, wherein the second processing tool is operable to form a film layer over the upper surface by performing a second plasma treatment to a base layer of the semiconductor substrate. The ion implantation apparatus may further include a third processing tool in a third chamber, wherein the third chamber is connected to the first and second chambers by the load-lock system, wherein the third processing tool is operable to perform an implant process to crystallize the film layer, and wherein the implant process comprises delivering an ion species to the film layer while the semiconductor substrate is at a temperature greater than 100° C. The semiconductor substrate is maintained under vacuum over a process duration spanning the first plasma treatment, the second plasma treatment, and the implant process, and during transfer of the semiconductor substrate between the first chamber, the second chamber, and the third chamber.

### BRIEF DESCRIPTION OF THE DRAWINGS

The accompanying drawings illustrate exemplary approaches of the disclosure, including the practical application of the principles thereof, as follows:

FIGS. 1A-1D illustrate exemplary operations involved in forming a crystallized film layer over a substrate according to embodiments of the disclosure;

FIGS. 2A-2D illustrate exemplary operations involved in forming a crystallized film layer over three-dimensional structures arrayed on a substrate according to embodiments of the disclosure;

FIGS. 3A-3D illustrate exemplary operations involved in forming a crystallized film layer over three-dimensional structures arrayed on a substrate according to embodiments of the disclosure;

FIGS. 4A-4E illustrate exemplary operations involved in forming a crystallized film layer over three-dimensional structures arrayed on a substrate according to embodiments of the disclosure;

FIG. 5 is a schematic diagram of a cluster tool/ion implantation apparatus according to embodiments of the disclosure;

FIG. 6 is a schematic diagram of a system for directing radicals into the semiconductor structure, in accordance with embodiments of the present disclosure; and

FIG. 7 illustrates a schematic diagram of a beamline processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, devices, and systems in accordance with the present disclosure will now be described more fully hereinafter with reference to the accompanying drawings, where various embodiments are shown. The methods, devices, and systems may be embodied in many different forms and are not to be construed as being limited to the embodiments set forth herein. Instead, these embodiments are provided so the disclosure will be thorough and complete, and will fully convey the scope of the methods to those skilled in the art.

In the embodiments described herein, the present inventors have identified novel approaches for creating single-crystal materials, epitaxially grown via ion beam induced epitaxial crystallization (IBIEC), from an interface of a single-crystal substrate or of a three-dimensional structure arrayed on a substrate and a deposited film. A single semiconductor cluster tool with different process chambers may be used to achieve this result in a continuous process flow.

In some cases, a layer of defects/non-crystalline material (i.e., native oxide or residue from previous device fabrication process steps) may be present along the substrate, which must be cleaned prior to deposition of the film. After deposition, an implant step may be performed to crystallize the material of the deposited film. This can be performed for continuous films and/or for regions of amorphous or polycrystalline material deposited on 3D crystalline structures, where the 3D structures would have been created by patterning and etching into the crystalline substrate. For example, an amorphous silicon may be deposited and reformed into a crystalline lattice via an approximately 450-500 C heated implant. The material deposition and IBIEC steps are performed consecutively in one integrated process flow, without breaking vacuum, to produce the desired high-quality crystalline Si film or region. If the vacuum is broken and native oxide re-forms before the deposition and ion implantation steps, the crystallization does not occur as desired.

Advantageously, no anneal is necessary after the film deposition and IBIEC treatment. Performing these steps at a lower thermal budget significantly reduces cost, and enables integration with metal (e.g., copper) interconnects and buried power rails. Furthermore, the IBIEC-causing implant can itself be used to add dopants to the final crystalline film/region, which would reduce process flow complexity while improving film quality. The approaches of the present disclosure are improvements over the existing state-of-the-art, e.g., those in which dopant species are implanted in amorphous semiconductor films (i.e., aSi) followed by a high-temperature thermal anneal to enable epitaxial crystallization.

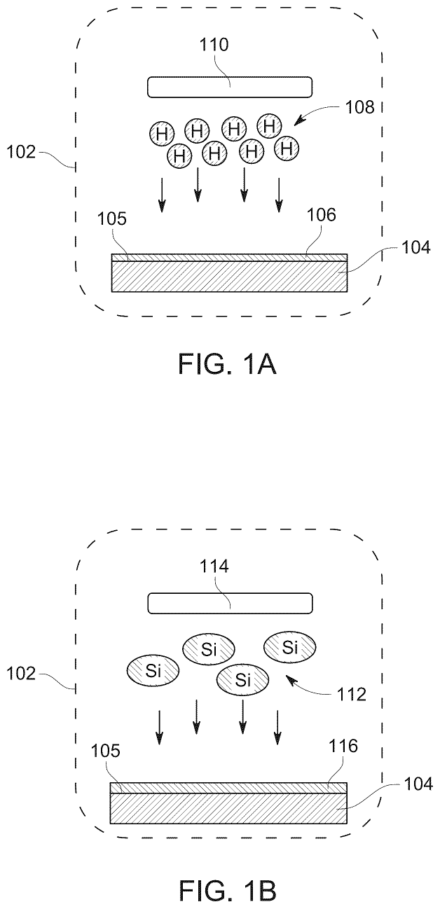

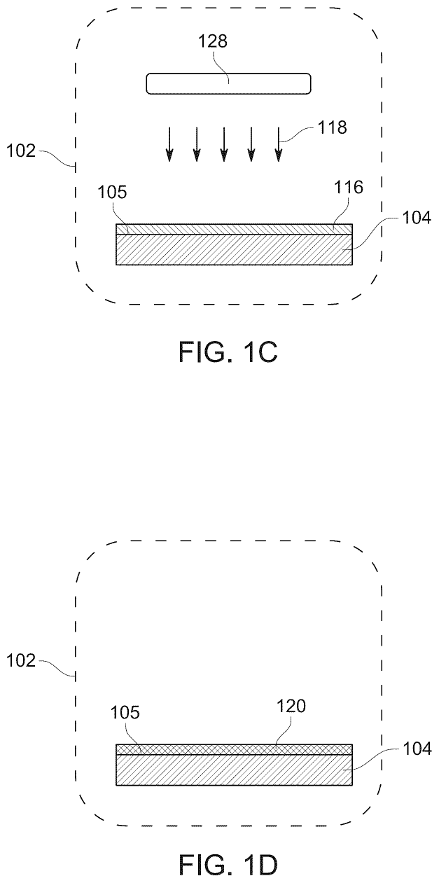

FIGS. 1A-1D illustrate exemplary operations involved in creating a crystalline film over a semiconductor substrate according to embodiments of the disclosure. Turning in particular to FIG. 1A, there is shown a first instance where a semiconductor substrate 100 is provided in a semiconductor processing apparatus 102 or system. The semiconductor processing apparatus 102 may represent a beamline ion implanter or other apparatus suitable to perform ion implantation, integrated with one or more other semiconductor processing chambers or locations that house the semiconductor substrate 100 during various processes to be performed.

While the semiconductor substrate 100 is located within the semiconductor processing apparatus 102, it may be understood that high vacuum conditions are maintained. For example, during ion implantation of the semiconductor substrate 100, vacuum levels of less than 10e−3 torr may be maintained in the end station housing the semiconductor substrate 100. During other processing operations, such as plasma-based operations, the vacuum levels of less than 10e−1 torr may be maintained, while during idle periods, vacuum levels of less than 10e−4 torr may be maintained according to non-limiting embodiments of the disclosure. Furthermore, exposure to ambient gaseous species outside of the semiconductor processing apparatus 102 may be precluded during and between the operations shown in FIGS. 1A-1D.

At the stage represented in FIG. 1A, the semiconductor substrate 100 may be placed into the semiconductor processing apparatus 102, after having received processing through multiple operations in order to synthesize devices, such as logic devices, memory devices, or other devices to receive processing for the purposes of deposition and doping of additional semiconductor film layers. In the non-limiting example shown, the semiconductor substrate 100 may include a substrate base 104, formed of monocrystalline semiconductor material. In some embodiments, the semiconductor substrate 100 may also include a residue or native oxide layer 106, disposed on an exposed/upper surface 105 thereof. As depicted in FIG. 1A, the substrate base 104 and native oxide layer 106 may represent any suitable portion of a semiconductor substrate, including patterned regions of a semiconductor device, according to various embodiments of the disclosure. The native oxide layer 106 may represent a layer formed after processing to remove any other materials from the surface of the substrate base 104. The formation of native oxide on silicon and like semiconductors in well-known and will not be discussed in detail herein. However, even when monocrystalline silicon is processed to remove any oxide or other non-silicon material from an outer surface, a native oxide may tend to form upon exposure to oxygen-containing (including water vapor) atmosphere, such as the ambient outside of a vacuum processing tool. Moreover, native oxide tends to be self-limiting in thickness, such that the thickness of the native oxide layer 106 may be assumed to be no more than 4 nm-8 nm in some non-limiting embodiments.

As further shown in FIG. 1A, the upper surface 105 of semiconductor substrate 100 may be exposed to a first plasma treatment, such as a plasma clean operation. Initially, the upper surface 105 may be covered with up to several nm of native oxide, represented by the native oxide layer 106. In some embodiments, the plasma clean operation may employ a plasma source 110 that is located in the semiconductor processing apparatus 102. The plasma source 110 may represent any suitable apparatus to generate a plasma, and in some instances may represent an RF radical source. In any case, the plasma source 110 may generate cleaning species 108, which species may represent a combination of ions and neutrals, including radicals.

In the case of the cleaning species 108 including ions, during the plasma clean operation, the energy of the ions may be maintained below 100 eV, such as in the range of several eV to 30 eV, in some non-limiting embodiments. In some embodiments, the cleaning species 108 may represent known reactive species that tend to chemically react to etch the native oxide layer 106, even when the energy of such reactive species is on the order of several eV. In various embodiments, the cleaning species 108 may selectively etch the native oxide layer 106 with respect to the substrate base 104. As such, the native oxide layer 106 may be removed from the substrate base 104 with little or no etching of the substrate base 104, and thus little or no damage to the substrate base 104, due to the low energy and etch selectivity of the cleaning species 108.

According to some embodiments, the plasma clean operation of FIG. 1A may be accomplished by generating hydrogen species in a plasma chamber of plasma source 110, and directing the hydrogen species to the upper surface 105 when the substrate 100 is at a cleaning temperature between room temperature and 100° C. The hydrogen species may be ionized hydrogen with noble gas dilution. In some non-limiting embodiments, the noble gas dilution may be Xenon (Xe) or Argon (Ar) to promote removal of the native oxide layer 106. The Xe or Ar ion bombardment of the upper surface 105 produces excited SiOx states, which then chemically react with the hydrogen radicals and are desorbed from the upper surface 105. The hydrogen radicals extracted from the plasma chamber reach the unbiased, room-temperature wafer at an energy of approximately 1-100 eV, while the pressure in the process chamber is carefully moderated, creating a processing regime where the native oxide layer 106 is removed without etching the underlying substrate base 104.

In some embodiments, the plasma clean operation may involve a plurality of sub-operations. For example, a first plasma clean sub-operation may be performed by generating a cleaning species from a plasma source that reacts to remove a portion of or all of the native oxide layer 106. This cleaning species may be a species different from hydrogen, for example. A second plasma clean sub-operation may then involve generating a hydrogen plasma and directing the hydrogen species to the upper surface 105 to remove any residual oxide, carbon, or other contaminant and to terminate the upper surface 105 with a hydrogen passivation. In other examples, just hydrogen species may be used to perform native oxide removal and hydrogen termination. In any case, the plasma clean operation may be completed by generating a hydrogen plasma and directing hydrogen species to the upper surface 105 to form a hydrogen passivation on the upper surface 105. Said differently, the plasma clean operation of FIG. 1A may considered to involve the sub-operations of native oxide removal followed by hydrogen termination of the upper surface 105. Likewise, in some embodiments, the cleaning species 108 may represent more than one species, such as a separate non-hydrogen species to etch the native oxide layer 106, as well as a hydrogen species to hydrogen-passivate the upper surface 105 after native oxide layer 106 removal.

Turning now to FIG. 1B, there is shown an instance, subsequent to the instance of FIG. 1A, where a deposition of a film layer 116 is performed on the upper surface 105 of the semiconductor substrate 100. The deposition may be performed by a second plasma source 114, located in the semiconductor processing apparatus 102. In some embodiments, the second plasma source 114 may or may not be the same source as plasma source 110. The deposition of the film layer 116 may be performed by generating a plasma of a deposition species 112. The deposition species 112 may be an ion or radical, and may be directed to the upper surface 105. For example, the film layer 116 may be formed as an amorphous silicon (aSi) or silicon germanium (SiGe), and the gas source for the deposition species may be silane (SiH4). As will be described in further detail herein, the deposition species 112 may be delivered vertically or at a non-zero angle relative to a perpendicular extending from the upper surface 105.

In various non-limiting embodiments of the disclosure, the deposition species 112 may be provided to the upper surface 105 at an energy that may vary from several eV to 100 eV. As such, the energy of the deposition species 112 may be such that little sputtering takes place during deposition of the deposition species 112, resulting in little to no damage to region at or near the upper surface 105. In accordance with various embodiments, the film layer 116 may have a thickness in the range of 1 nm to 25 nm at the processing stage represented in FIG. 1B, after formation is completed. In some embodiments, this thickness may be tailored according to various considerations, including the targeted dopant concentration in the substrate base 104 near the upper surface 105, and other factors. Although not shown, in another embodiment, the hydrogen radical treatment demonstrated in FIG. 1A may be performed after deposition of the film layer 116. In still other embodiments, the radical treatment may be performed both before and after formation of the film layer 116.

Turning now to FIG. 1C, there is shown a subsequent instance where the semiconductor substrate 100 is exposed to an ion implantation process on the upper surface 105 when the film layer 116 is disposed on the substrate base 104. In so doing, the implant process introduces an ion species 118 into the semiconductor substrate 100 and, in particular, into the film layer 116 and/or the substrate base 104, which causes ion beam-induced epitaxial crystallization of the film layer 116. Note that ion species 118 may be provided via an implanter 128, which may be located in the semiconductor processing apparatus 102. In various embodiments, the implanter 128 may be a beamline ion implanter or a plasma doping tool. In some examples, the ion species 118 may be Si, Ge, boron (B), arsenic (As), phosphorous (P), or other suitable element, wherein B, P, As, etc., will dope the film layer 116.

In various non-limiting embodiments, the ion species 118 may have an ion energy between 0.2 keV-60 keV, and in some cases between 0.5 keV and 7 keV, depending upon the material of the ion species 118 and the thickness of the film layer 116, and may be delivered at a normal incidence (e.g., vertical) or with an angled ion beam. Furthermore, the ion species 118 may be delivered to the semiconductor substrate 100 while a platform (not shown) supporting the semiconductor substrate 100 is maintained at a temperature less than approximately 500 C, e.g., 450-500C in the case the film layer 116 is aSi. When the film layer 116 is SiGe, the ion species 118 may be delivered while the semiconductor substrate 100 is maintained at a relatively lower temperature (e.g., approximately 200-300 C). When the film layer 116 is Ge, the temperature may be even lower yet, e.g., 100-200C. In yet other embodiments, the film layer 116 may be an amorphous or polycrystalline silicon-phosphorous film. In any case, this elevated temperature ion implantation causes an ion beam-induced epitaxial crystallization process in the film layer 116 in which a crystalline lattice is grown beginning at the interface of the film layer 116 and the substrate base 104. This crystalline layer 120 is demonstrated in FIG. 1D.

In the case where the ion species 118 is not silicon and the film layer 116 is amorphous or polycrystalline silicon, then the resulting crystalline silicon film is also doped with the implanted element. The crystalline layer 120 may be formed by implantation of ion species 118 directly into the substrate base film layer 116, or alternately by the driving of dopant material or element from the film layer 116 into the substrate base as a result of knock-on collisions from the ion species 118, for example. In other words, an implant range for the ion species 118 may be greater than a thickness of the film layer 116 before the implant process, such that at least some ions of ion species 118 are implanted directly into the substrate base 104. As such, the doped layer 120 may represent a mixture of elements from the film layer 116 and dopant from the ion species 118. Advantageously, no high temperature thermal process (e.g., thermal anneal) is necessary to drive in the dopants.

Note that according to various embodiments, the operations of FIGS. 1A-1D may be repeated in cyclical fashion to achieve a target dopant dose within a substrate. Said differently, the plasma clean, the deposition of the film layer, and the implant process may be performed as an implant cycle, where the implant cycle is repeated one or more times to implant a target dopant level into the substrate.

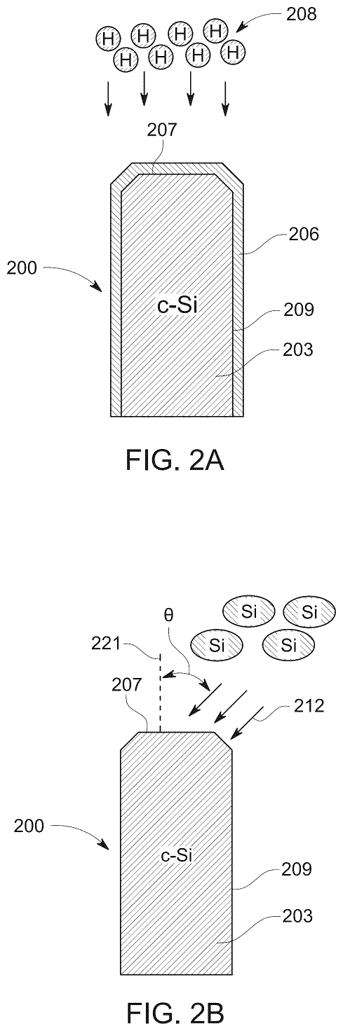

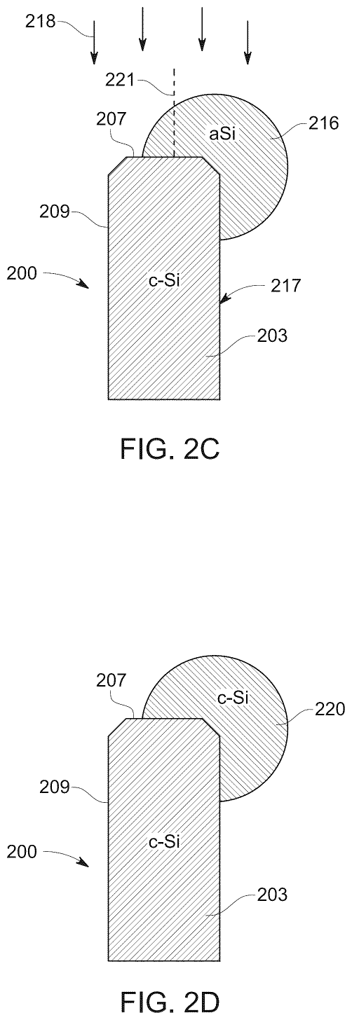

Turning now to FIGS. 2A-2D, principles of the present disclosure will be described in greater detail. Depicted in this non-limiting example is a portion of a 3D fin structure 203 on a semiconductor substrate 200, wherein the fin structure 203 may extend vertically from a substrate base (not shown). The fin structure 203 may be part of a fin field effect transistor (finFET) device. The fin structure 203 and the substrate base may be formed of a monocrystalline semiconductor material (e.g., c-Si). As shown in FIG. 2A, the semiconductor substrate 200 may also include a native oxide layer 206 present on a top surface 307 and a sidewall 209 of the fin structure 203. In some non-limiting embodiments, the native oxide layer 206 may be silicon dioxide (SiO₂).

The top surface 207 and the sidewall 209 of the fin structure 203 of the semiconductor substrate 200 may be exposed to a first plasma treatment, such as a plasma clean operation. In some embodiments, the plasma clean operation may employ a plasma source, such as the plasma source 110 located in the semiconductor processing apparatus 102, as described above. The plasma source 110 generates cleaning species 208, which may be hydrogen radicals in the current example. The first plasma treatment will remove the native oxide layer 206.

As shown in FIG. 2B, a second plasma treatment may be performed in which a deposition species 212 is delivered to the fin structure 203. The deposition species 212 may be an ion or radical, and may be directed to the top surface 207 and the sidewall 209 of the fin structure 203 at a non-zero angle ‘0’ relative to a perpendicular 221 extending from the top surface 207. In the embodiment shown, the deposition species 212 may be Si, which is directed to the semiconductor substrate 200 using a plasma source, such as the second plasma source 114 of the semiconductor processing apparatus 102, as described above. The deposition species 212 may impact only a portion of the top surface 207 and the sidewall 209, resulting in the film layer 216 shown in FIG. 2C. In this embodiment, the film layer 216 may be formed as an a-Si layer or a SiGe layer, and the gas source for the deposition species may be SiH4. The film layer 216 may be prevented from being formed on a lower portion 217 of the sidewall 209 due to the non-zero angle ‘θ’ of delivery of the deposition species 212.

As further shown in FIG. 2C, the fin structure 203 may then be exposed to an implant process, which impacts the film layer 216 formed on the top surface 207 and the sidewall 209 of the fin structure 203. In so doing, the implant process introduces an ion species 218 into the semiconductor substrate 200 and, in particular, into the film layer 216 of the fin structure 203, which causes ion beam-induced epitaxial crystallization of the silicon of the film layer 216. Note that ion species 218 may be provided as an ion beam in a beamline ion implanter or plasma doping chamber, such as the implanter 128 located in the semiconductor processing apparatus 102, as described above. In some examples the ion species 218 may be Si, Ge, B, As, P, or other suitable element, which may dope the film layer 216 once implanted. Although shown as being delivered substantially vertically, in other embodiments the ion species 218 may be delivered at a non-zero angle relative to the perpendicular 221.

The ion species 218 may be delivered to the semiconductor substrate 200 while a platform (not shown) supporting the semiconductor substrate 200 is maintained at an elevated temperature, e.g., between 400-500 C. As a result of the heated implant, the film layer 216 is transformed to crystallized layer 220, as shown in FIG. 2D. The material and composition of the crystallized layer 220 and the fin structure 203 may be the same following the implant process.

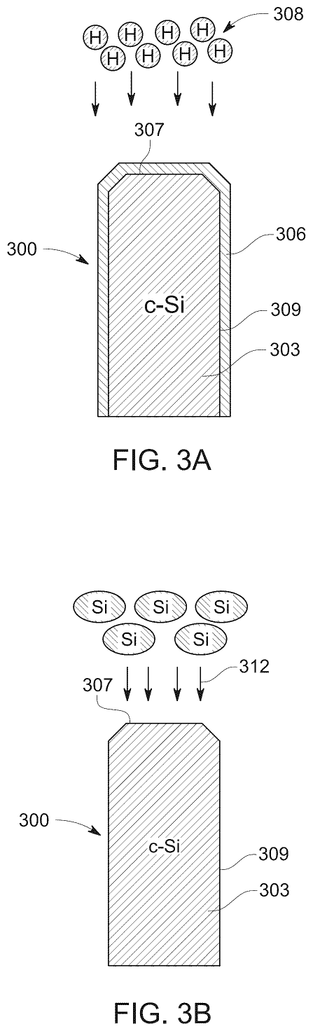

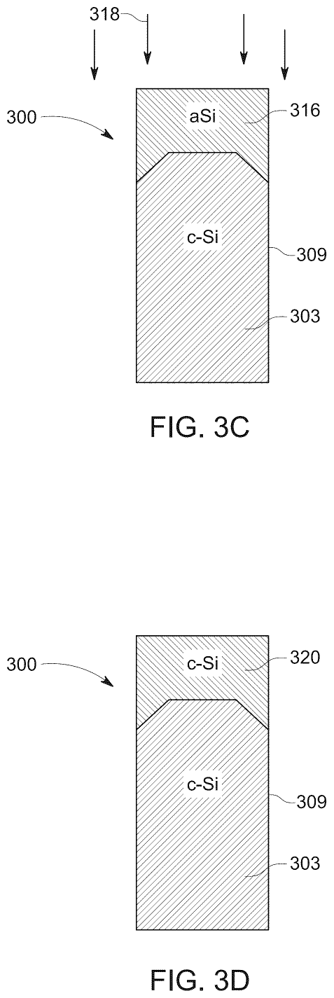

Turning now to FIGS. 3A-3D, principles of the present disclosure will be described in greater detail. Depicted in this non-limiting example is a portion of a 3D fin structure 303 of a semiconductor substrate 300, wherein the fin structure 303 may extend vertically from a substrate base (not shown). The fin structure 303 may be part of a finFET device, and may be the same or similar to the fin structure 203 described above. As such, only certain aspects of the fin structure 303 and associated processing steps will be hereinafter described for the sake of brevity.

As shown in FIG. 3A, the semiconductor substrate 300 may include a native oxide layer 306 present on a top surface 307 and a sidewall 309 of the fin structure 303. The semiconductor substrate 300 may be exposed to a first plasma treatment, such as a plasma clean operation including cleaning species 308, which may be hydrogen radicals in the current example. The first plasma treatment will remove the native oxide layer 306.

As shown in FIG. 3B, a second plasma treatment may be performed in which a deposition species 312 is delivered to the fin structure 303. The deposition species 312 may be an ion or radical, and may be directed vertically to the top surface 307. In the embodiment shown, the deposition species 312 may generally impact only the top surface 307 of the fin structure 303 without significantly impacting and the sidewall 309, resulting in the film layer 316 shown in FIG. 3C. In this embodiment, the film layer 316 may be formed as an a-Si layer or a SiGe layer, and the gas source for the deposition species may be SiH4. The film layer 316 may be prevented from being formed on the sidewall 309 due to the straight/vertically downward angle of delivery of the deposition species 312.

As further shown in FIG. 3C, the fin structure 303 may then be exposed to an implant process, which impacts the film layer 316. In so doing, the implant process introduces an ion species 318 into the semiconductor substrate 300 and, in particular, into the film layer 316, which causes ion beam-induced epitaxial crystallization of the silicon of the film layer 316. Although shown as being delivered substantially vertically, in other embodiments the ion species 318 may be delivered at a non-zero angle relative to a perpendicular (not shown) extending from the top surface 307 of the fin structure 303.

The ion species 318 may be delivered to the semiconductor substrate 300 while the semiconductor substrate 300 is at an elevated temperature, e.g., between 400-500 C. As a result of the heated implant, the film layer 316 is transformed to crystallized layer 320, as shown in FIG. 3D.

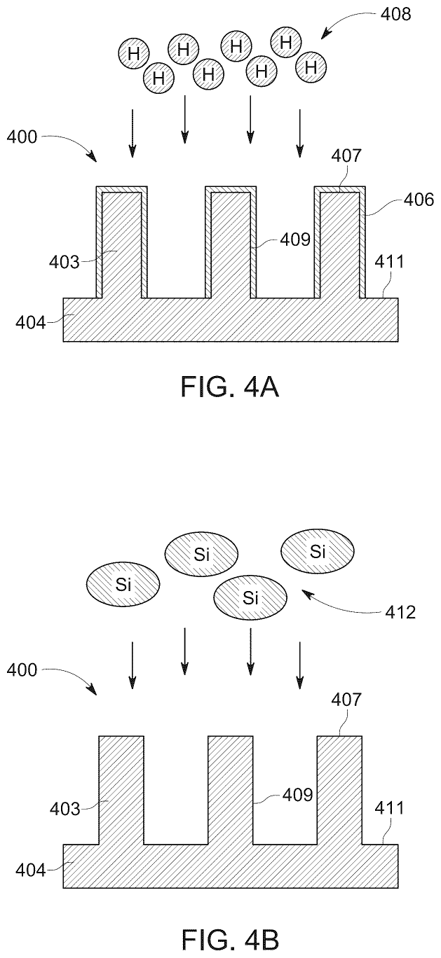

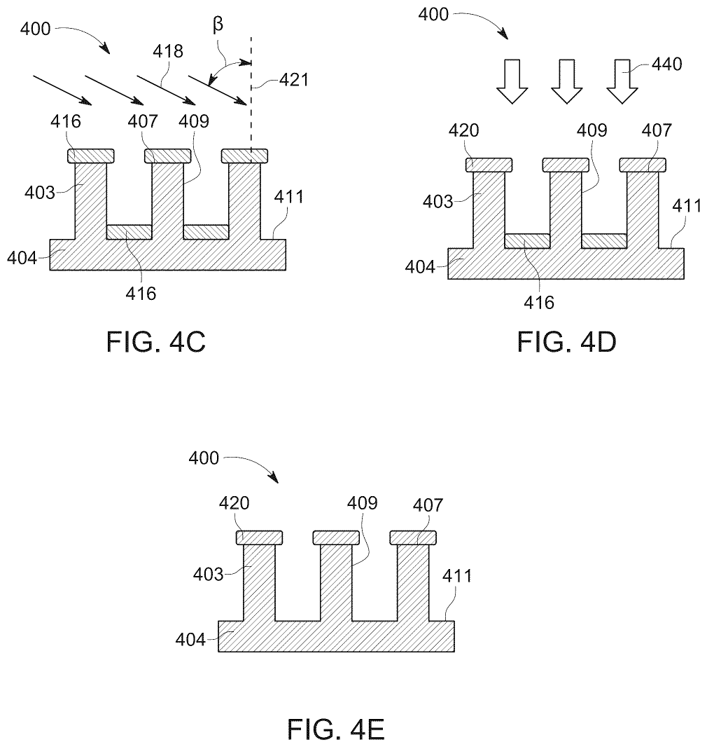

Turning now to FIGS. 4A-4E, principles of the present disclosure will be described in greater detail. Depicted in this non-limiting example is a semiconductor substrate 400 including a plurality of fin structures 403 extending vertically from a substrate base 404. The plurality of fin structures 403 may be part of a fin field effect transistor (finFET) device. Each of the plurality of fin structures 403 may include a top surface 407, a sidewall 409, and a base surface 411 extending between adjacent fin structure 403.

As shown in FIG. 4A, the semiconductor substrate 400 may include a native oxide layer 406 present on the top surface 407 and the sidewalls 409 of each fin structure 403. In some embodiments, the native oxide layer 406 may also be present on the base surface 411. The semiconductor substrate 400 may be exposed to a first plasma treatment, such as a plasma clean operation including cleaning species 408, which may be hydrogen radicals in the current example. The first plasma treatment will remove the native oxide layer 406.

As shown in FIG. 4B, a second plasma treatment may be performed in which a deposition species 412 (e.g., SiH4) is delivered to the semiconductor substrate 400. The deposition species 412 may be an ion or radical, and may be directed to the top surface 407 and to the base surface 411 to form film layer 416, as shown in FIG. 4C. In this non-limiting embodiment, the film layer 416 may be formed as an a-Si layer or a SiGe layer, which is generally prevented from being formed on the sidewalls 409 of the fin structure 403 due to the straight/vertically downward angle of delivery of the deposition species 412.

As further shown in FIG. 4C, the semiconductor substrate 400 may then be exposed to an angled implant process, which impacts the film layer 416 formed on the top surface 407 of each fin structure 403. In so doing, the implant process introduces an ion species 418 into the film layer 416, which causes ion beam-induced epitaxial crystallization of the silicon of the film layer 416. Because the ion species 418 is being delivered at a non-zero angle ‘B’ relative to a perpendicular 421 extending from the top surface 407, only the film layer 416 along the top surface 407 is reached. That is, the film layer 416 between fin structure 403 is generally not impacted. The ion species 418 may be delivered to the semiconductor substrate 400 at an elevated temperature, e.g., between 400-500 C. As a result of the heated implant, the film layer 416 is transformed to crystallized layer 420, as shown in FIG. 4D.

As further shown in FIG. 4D, the semiconductor substrate 400 may be subjected to a subtractive process 440, such as an ion etch in which only the film layer 416 between the fin structures 403 is significantly impacted. In some embodiments, as shown in FIG. 4E, the subtractive process 440 may be an aSi selective etch, which does not remove the crystallized layer 420 from the fin structures 403.

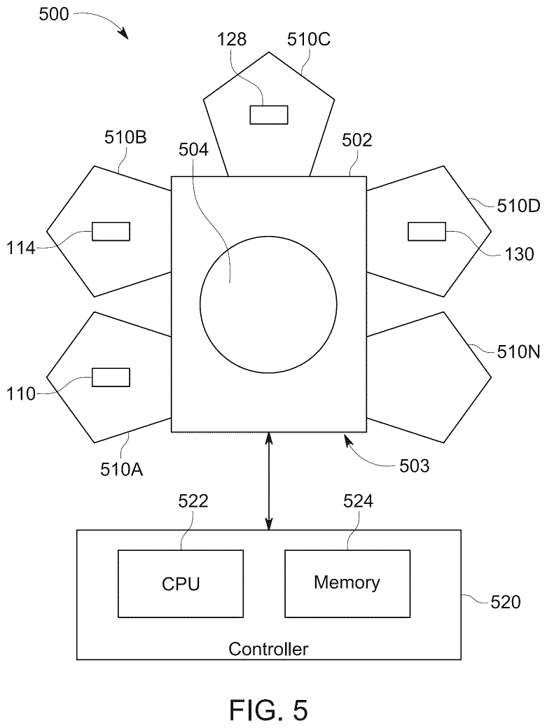

Turning now to FIG. 5, an example semiconductor processing apparatus 500 will be described. In some embodiments, the semiconductor processing apparatus 500 may be a cluster tool operable to perform processes necessary to form the devices described herein. Although non-limiting, the semiconductor processing apparatus 500 may include at least one central transfer station/chamber 502 of a load-lock system 503, and one or more robots 504 within the transfer station/chamber 502, wherein the robot 504 is operable to move a robot blade and a wafer to and from each of a plurality of processing chambers 510A-510N connected with, or positioned adjacent to, the transfer station/chamber 502, and without breaking vacuum. In some embodiments, the processing chambers 510A-510N may support various ion treatments including ion implantation, material deposition, material etching, and more. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 510A may include a first processing tool operable to perform a first plasma treatment on a semiconductor substrate, e.g., to remove a native oxide layer along an upper surface of the semiconductor substrate. The first processing tool may be the same or similar to the plasma source 110 described herein.

Processing chamber 510B may include a second processing tool operable to form a film layer over the upper surface of the semiconductor device by performing a second plasma treatment to a base layer of the semiconductor substrate. In some embodiments, the second processing tool may be the same or similar to the second plasma source 114 described herein.

Processing chamber 510C may include a third processing tool operable to perform an implant process to crystallize the film layer, wherein the implant process comprises delivering an ion species to the film layer while the semiconductor substrate is at a temperature greater than 100° C. In some embodiments, the third processing tool may be the same or similar to the implanter 128 described herein. As the semiconductor substrate passes between processing chambers 510A-510C, the semiconductor substrate is maintained under vacuum over a process duration spanning the first plasma treatment, the second plasma treatment, and the implant process.

Processing chamber 510D may include a fourth processing tool, such as a reactive ion etching tool 130, which may be used to form 3D device structures, such as a finFET device, and to remove one or more layers of the semiconductor substrate, such as the film layer between the fin structures (FIG. 4E).

A system controller 520 is in communication with the robot 504, the transfer station/chamber 502, and the plurality of processing chambers 510A-510N. The system controller 520 can be any suitable component that can control the processing chambers 510A-510N and robot(s) 504, as well as the processes occurring within the process chambers 510A-510N. For example, the system controller 520 can be a computer including a central processing unit 522, memory 524, suitable circuits/logic/instructions, and storage.

Processes or instructions may generally be stored in the memory 524 of the system controller 520 as a software routine that, when executed by the processor 522, causes the processing chambers 510A-510N to perform processes of the present disclosure. The software routine may also be stored and/or executed by a second processor (not shown) that is remotely located from the hardware being controlled by the processor 522. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 522, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

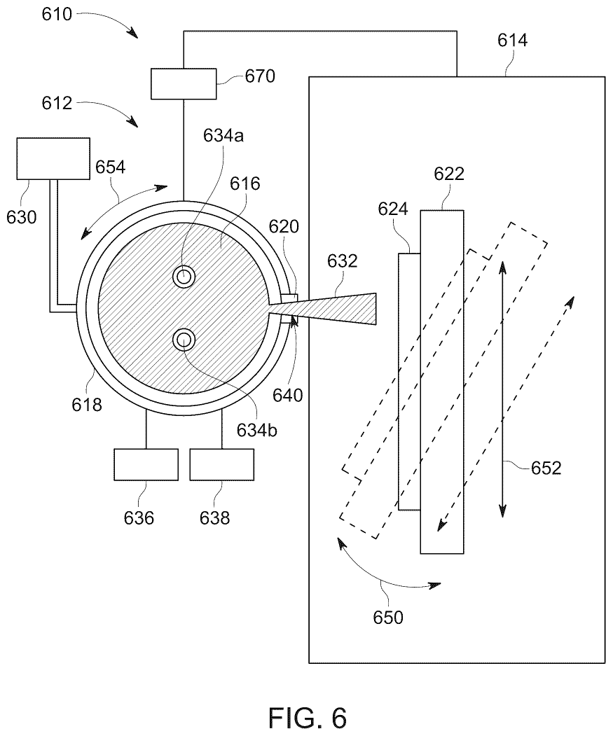

FIG. 6 illustrates a portion of a system 610 useful to perform processes described herein, such as the first plasma treatment or the second plasma treatment. The system 610 may generally include a plasma source 612 disposed adjacent a process chamber 614. In various embodiments, the system 610 may correspond to the plasma source 110 or to the second plasma source 114, described above. The plasma source 612 may be adapted to generate an energetic plasma 616 in a plasma chamber 618, and to emit the plasma 616, e.g., through a nozzle 620 of the plasma chamber 618, or alternatively with a second plate with a separate aperture situated a specific distance away from 618. While the plasma chamber 618 is depicted as being generally cylindrical in shape, the present disclosure is not limited in this regard, and the plasma chamber 618 may be implemented in a variety of alterative shapes and configurations.

The process chamber 614 may contain a wafer support or platen 622 adapted to support a substrate 624 (e.g., a silicon wafer) in a confronting relationship with the nozzle 620 of the plasma chamber 618. In various embodiments, the platen 622 may be adapted to forcibly retain the substrate 624, such as via electrostatic clamping or mechanical clamping. Additionally, the platen 622 may include a heating element (not shown) for controllably heating the substrate 624 to a desired temperature (e.g., a temperature in a range between room temperature and 450 degrees Celsius) to enhance deposition processes.

The plasma source 612 of the system 610 may be configured to generate the plasma 616 from a gaseous species supplied to the plasma chamber 618 by one or more gas sources 630. The plasma 616 (and particularly free radicals within the plasma) may be directed at the substrate 624. In some non-limiting embodiments, the plasma 616 is delivered to the substrate 624 as a ribbon beam 632. In various embodiments, the plasma source 612 may be a radio frequency (RF) plasma source (e.g., an inductively coupled plasma (ICP) source, a capacitively coupled plasma (CCP) source, a helicon source, an electron cyclotron resonance (ECR) source, etc.). For example, the plasma source 612 may include electrodes 634a, 634b, an RF generator 636, and an RF matching network 638 for igniting and sustaining the plasma 616 in a manner familiar to those of ordinary skill in the art. The present disclosure is not limited in this regard.

The plasma 616 generated in the plasma chamber 618 may contain ionized gas species (ions), electrons, excited neutrals, and free radicals. When a plasma enhanced chemical vapor deposition (PECVD) system is used, the substrate 624 may be located in the same chamber as the plasma 616, and free radicals within the plasma are distributed over the surface of the substrate 624 in a directionally-nonspecific, isotropic manner to form a thin film of generally uniform thickness on the exposed surface(s) of the substrate. In another embodiment, the plasma chamber 618 of the system 610 is separate from the process chamber 614 where the platen 622 and the substrate 624 reside, and a collimated ribbon beam 632 containing free radicals of the plasma 616 is extracted from the plasma chamber 618 and is directed at the substrate 624. This is achieved by establishing a pressure differential between the plasma chamber 618 and the process chamber 614, and by collimating the radical beam.

In a non-limiting example, the radical beam may be extracted through the nozzle 620 or a second aperture plate having an elongated profile. With regard to the pressure differential, the process chamber 614 may be maintained at a first pressure, and the plasma chamber 618 may be maintained at a second pressure higher than the first pressure. In various examples, the first pressure in the process chamber may be in a range of 10−6 torr to 10−2 torr, and the second pressure in the plasma chamber 618 may be in a range of 1 millitorr to 1 torr. The present disclosure is not limited in this regard. Thus, the pressure differential between the plasma chamber 618 and the process chamber 614 may provide a motive force for driving free radicals in the plasma 616 from the plasma chamber 618 into the process chamber 614 in the form of the ribbon beam 632.

The platen 622 may be rotatable and movable for pivoting and scanning the substrate 624 relative to the plasma chamber 618 as indicated by arrows 650 and 652. Additionally, or alternatively, the plasma chamber 618 may be rotatable about its long axis as indicated by the arrow 654. Thus, the collimated, free radical-containing ribbon beam 632 may be projected onto the substrate 624 at various angles in a highly directional manner.

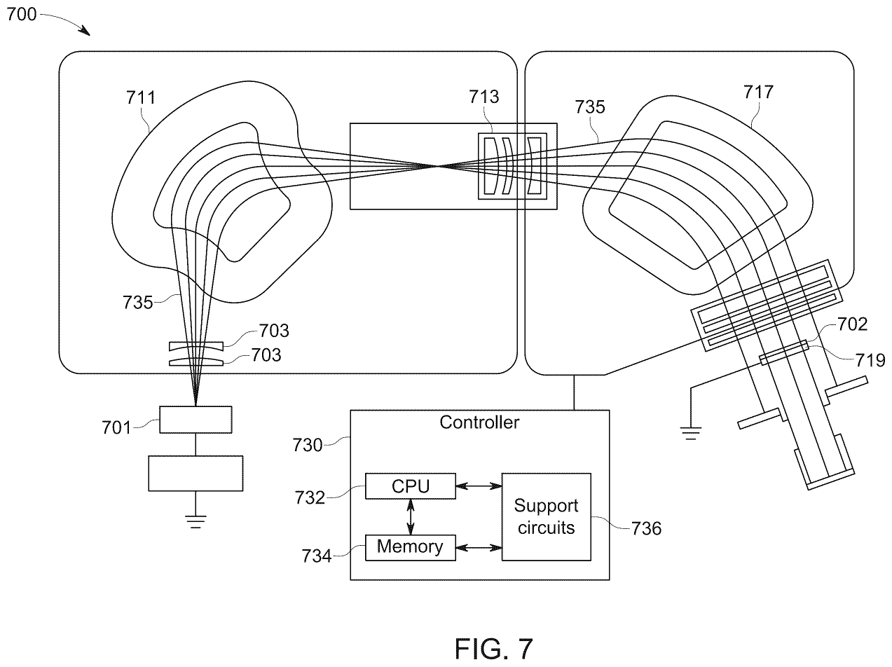

FIG. 7 illustrates a schematic diagram of a processing apparatus 700 useful to perform processes described herein, such as the high temperature ion implantation. The processing apparatus 700 may correspond to the implanter 128 described above. One example of a beamline ion implanter is the Varian VIISTA® Trident, available from Applied Materials Inc., Santa Clara, CA. The processing apparatus 700 may include an ion source 701 for generating ions. For example, the ion source 701 may provide an ion implant, such as the ion implant for introducing ion species 118, 218, 318, and 418, as described above.

The processing apparatus 700 may also include a series of beam-line components. Examples of beam-line components may include extraction electrodes 703, a magnetic mass analyzer 711, a plurality of lenses 713, and a beam parallelizer 717. The processing apparatus 700 may also include a platen 719 for supporting a wafer or substrate 702 to be processed. In some embodiments, the platen 719 may be heated using an external or embedded heating element 724, such as a resistive heater, or may be heated using radiant heat, such as heating lamps disposed above or below the platen 719. In other embodiments, the heating element may additionally, or alternatively, be located in a load lock chamber or a separate pre-heat chamber to pre-heat the wafer 702 before it reaches the platen 719. Even with a pre-heat, the platen 719 may include the internal heating element 724. The substrate 702 may be moved in one or more dimensions (e.g. translate, rotate, tilt, etc.) by a component sometimes referred to as a “roplat” (not shown). It is also contemplated that the processing apparatus 700 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 701. Thereafter, the extracted ions 735 travel in a beam-like state along the beam-line components and may be implanted in the substrate 702. Similar to a series of optical lenses that manipulate a light beam, the beam-line components manipulate the extracted ions 735 along the ion beam. In such a manner, the extracted ions 735 are manipulated by the beam-line components while the extracted ions 735 are directed toward the substrate 702. It is contemplated that the apparatus 700 may provide for improved mass selection to implant desired ions while reducing the probability of undesirable ions (impurities) being implanted in the substrate 702.

In some embodiments, the processing apparatus 700 can be controlled by a processor-based system controller such as controller 730, which may include a programmable central processing unit (CPU) 732 that is operable with a memory 734 and a mass storage device, an input control unit, and a display unit (not shown), such as power supplies, clocks, cache, input/output (I/O) circuits, and the like, coupled to the various components of the processing apparatus 700 to facilitate control of the substrate processing. The controller 730 also includes hardware for monitoring substrate processing through sensors in the processing apparatus 700, including sensors monitoring the substrate position and sensors configured to receive feedback from and control a heating apparatus coupled to the processing apparatus 700. Other sensors that measure system parameters such as substrate temperature and the like, may also provide information to the controller 730. Support circuits 736 may be coupled to the CPU 732 for supporting the processor in a conventional manner. Implantation and other processes are generally stored in the memory 734, typically as a software routine. The software routine may also be stored and/or executed by a second CPU (not shown) that is remotely located from the hardware being controlled by the CPU 732.

In sum, embodiments described herein are directed to a semiconductor processing tool with the capability for hydrogen ion generation/wafer treatment, a deposition chamber capable of depositing amorphous silicon or silicon/germanium, as well as ion implantation of various desired species, and wherein all three capabilities are integrated in a single cluster tool sharing one or a plurality of load ports and vacuum transfer chambers between them, enabling the full process flows outlined above without breaking vacuum. In doing so, at least the following advantages are provided by the embodiments described herein. Firstly, a significantly reduced thermal budget and simplified process flow is achieved while producing improved crystalline silicon film quality. Secondly, the ability to dope Si film in a same step as epitaxial crystallization, with higher resulting film quality, improves throughput and reduces costs. Thirdly, for 3D device structures such as FinFETs, this process can be used to add aSi via directional or non-directional deposition processes and then convert it to crystalline silicon (doped if desired) in situ, which cannot be accomplished via other means, let alone at such low thermal budgets.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
performing a first plasma treatment on a semiconductor substrate to remove a residue layer along an upper surface of the semiconductor substrate;
forming a film layer over the upper surface by performing a second plasma treatment to a base layer of the semiconductor substrate; and
performing an implant process to crystallize the film layer, wherein the implant process comprises delivering an ion species to the film layer while the semiconductor substrate is at a temperature greater than 100° C.

2. The method of claim 1, wherein the first plasma treatment is performed by a first processing tool in a first chamber, wherein the second plasma treatment is performed by a second processing tool in a second chamber, wherein the implant process is performed by a third processing tool in a third chamber, and wherein the first chamber, the second chamber, and the third chamber are all part of a same semiconductor cluster tool.

3. The method of claim 2, wherein the semiconductor substrate is maintained under vacuum in the semiconductor cluster tool during the first plasma treatment, the second plasma treatment, the implant process, and all substrate transfer operations between processing chambers.

4. The method of claim 1, wherein forming the film layer comprises forming an amorphous silicon film layer directly atop the upper surface.

5. The method of claim 1, wherein the ion species of the implant process is delivered to the film layer at a non-zero angle relative to a perpendicular extending from the upper surface.

6. The method of claim 1, wherein the ion species of the implant process is delivered to the film layer while the semiconductor substrate is at a temperature less than 500° C., and wherein the ion species of the implant process is delivered to the film layer at an energy between 0.2 keV and 60 keV.

7. The method of claim 1, wherein the first plasma treatment comprises a hydrogen radical and a noble gas dilution species maintained at an energy below 100 eV.

8. The method of claim 1, wherein the implant process introduces a dopant element into the film layer simultaneously with the crystallization.

9. The method of claim 1, wherein the semiconductor substrate comprises a 3-dimensional structure.

10. A method of processing a film layer formed over a semiconductor substrate, the method comprising:
performing a first plasma treatment on a semiconductor substrate to remove a residue layer along an upper surface of the semiconductor substrate;
forming a film layer over the upper surface by performing a second plasma treatment to a base layer of the semiconductor substrate following removal of the residue; and
performing an implant process to crystallize the film layer, wherein the implant process comprises delivering an ion species to the film layer while the semiconductor substrate is at a temperature between 100° C. and 500° C., wherein the first plasma treatment is performed by a first processing tool in a first chamber, wherein the second plasma treatment is performed by a second processing tool in a second chamber, wherein the implant process is performed by a third processing tool in a third chamber, wherein the first chamber, the second chamber, and the third chamber are all part of a same semiconductor cluster tool, and wherein the semiconductor substrate is maintained under vacuum in the semiconductor cluster tool during the first plasma treatment, the second plasma treatment, the implant process, and during all substrate transfer operations between the first processing chamber, the second processing chamber, and the third processing chamber.

11. The method of claim 10, wherein forming the film layer comprises forming at least one of the following directly atop the upper surface: an amorphous or polycrystalline silicon film layer, an amorphous or polycrystalline silicon-germanium film layer, an amorphous or polycrystalline silicon-phosphorous film layer, and an amorphous or polycrystalline germanium film layer.

12. The method of claim 10, wherein the ion species of the implant process is delivered to the film layer at a non-zero angle relative to a perpendicular extending from the upper surface.

13. The method of claim 10, wherein the first plasma treatment comprises a hydrogen radical and a noble gas dilution species maintained at an energy below 100 eV, wherein the ion species of the implant process is delivered to the film layer while the semiconductor substrate is at a temperature less than 500° C., and wherein the ion species of the implant process is delivered to the film layer at an energy between 0.2 keV and 60 keV.

14. The method of claim 10, wherein the implant process introduces a dopant element into the film layer simultaneously with the crystallization.

15. The method of claim 10, wherein the semiconductor substrate comprises a plurality of 3-dimensional structures each comprising:
a top surface;
a sidewall connected with the top surface;
a base surface connected with the sidewall, wherein the film layer is formed along the top surface without being formed along a lower portion of the sidewall.

16. A semiconductor cluster tool, comprising:
a first processing tool in a first chamber, wherein the first processing tool is operable to perform a first plasma treatment on a semiconductor substrate to remove a native oxide layer along an upper surface of the semiconductor substrate;
a second processing tool in a second chamber, wherein the second processing tool is operable to form a film layer over the upper surface by performing a second plasma treatment to a base layer of the semiconductor substrate; and
a third processing tool in a third chamber, wherein the third processing tool is operable to perform an implant process to crystallize the film layer, wherein the implant process comprises delivering an ion species to the film layer while the semiconductor substrate is at a temperature greater than 100° C., wherein the first chamber, the second chamber, and the third chamber are all operably connected to a same load-lock system, and wherein the semiconductor substrate is maintained under vacuum during each of the following: the first plasma treatment, the second plasma treatment, the implant process, and transferring of the semiconductor substrate between the first chamber, the second chamber, and the third chamber.

17. The semiconductor cluster tool of claim 16, wherein the ion species of the implant process is delivered to the film layer at a non-zero angle relative to a perpendicular extending from the upper surface.

18. The semiconductor cluster tool of claim 16, wherein the ion species is delivered to the film layer while the semiconductor substrate is at a temperature below 500° C., and wherein the ion species of the implant process is delivered to the film layer at an energy between 0.2 keV and 60 keV.

19. The semiconductor cluster tool of claim 16, wherein the first plasma treatment comprises a hydrogen radical and a noble gas dilution species maintained at an energy below 100 eV.

20. The semiconductor cluster tool of claim 16, wherein the implant process by the third processing tool introduces a dopant element into the film layer simultaneously with the crystallization.
